(19) United States
(12) Patent Application Publication
(10) Pub. No.: US 2024/0038845 A1
(43) Pub. Date: Feb. 1, 2024

(54) LAYER STRUCTURES INCLUDING TWO-DIMENSIONAL CHANNEL LAYER, METHODS OF MANUFACTURING THE SAME, ELECTRONIC DEVICES INCLUDING 2D CHANNEL LAYER, AND ELECTRONIC APPARATUSES INCLUDING ELECTRONIC DEVICE

(71) Applicant: Samsung Electronics Co., Ltd., Suwon-si (KR)

(72) Inventors: Minseok YOO, Suwon-si (KR); Minsu SEOL, Suwon-si (KR); Junyoung KWON, Suwon-si (KR); Kyung-Eun BYUN, Suwon-si (KR)

(73) Assignee: Samsung Electronics Co., Ltd., Suwon-si (KR)

(21) Appl. No.: 18/335,487

(22) Filed: Jun. 15, 2023

(30) Foreign Application Priority Data
Jul. 27, 2022 (KR) 10-2022-0093504

(51) Int. Cl. H01L 29/10; H01L 29/778; H01L 29/78; H01L 29/66; H01L 29/417

(52) U.S. Cl. CPC H01L 29/1033; H01L 29/7786; H01L 29/785; H01L 29/66795; H01L 29/66431; H01L 29/41791

(57) ABSTRACT

A layer structure including a two-dimensional (2D) channel layer, a method of manufacturing a two-dimensional (2D) channel layer, an electronic device including the layer structure, and an electronic apparatus including the layer structure are disclosed. The layer structure may include a first substrate, a second substrate surrounded by the first substrate, and a 2D channel layer on the second substrate. An interfacial energy of the second substrate may be less than an interfacial energy of the first substrate. The method of manufacturing a 2D channel layer may include forming a second substrate to be surrounded by a first substrate, forming a precursor layer for forming a 2D channel on any one of the first and second substrates, and transforming the precursor layer into a liquid precursor layer. The interfacial energy of the second substrate may be less than the interfacial energy of the first substrate.

### CROSS-REFERENCE TO RELATED APPLICATION

This application is based on and claims priority under 35 U.S.C. § 119 to Korean Patent Application No. 10-2022-0093504, filed on Jul. 27, 2022 in the Korean Intellectual Property Office, the disclosure of which is incorporated by reference herein in its entirety.

### BACKGROUND

Various example embodiments relate to forming and applying a two-dimensional (2D) channel layer, and more particularly, to layer structures including a 2D channel layer, methods of forming the layer structures, electronic devices including a 2D channel layer formed by the method, and electronic apparatuses including the electronic devices.

With the advancement of semiconductor technology, the size of a semiconductor device may decrease as the degree of integration of the semiconductor device increases. As the miniaturization of semiconductor devices accelerates, performance limitations may appear due to scaling of 3D bulk materials. As one of the methods to overcome the scaling limitation, research into using a 2D layered material has been conducted.

Because a 2D layered material may be stable and may have high characteristics even at a thickness of 1 nm or less, it is spotlighted as a next-generation material that may overcome the performance degradation limit according to the scaling of 3D bulk materials. For example, in the case of a silicon (Si) channel, as a thickness of a channel decreases, mobility may decrease and threshold voltage Vth distribution may increase; and as the channel length decreases, performance degradation due to the short channel effect may become severe, and thus, a scaling limitation may occur.

However, in the case of a 2D layered material channel, for example, a 2D semiconductor material channel, the 2D layered material channel may have excellent performance even at a small thickness of 1 nm or less, and also may have a short channel effect that is less than that of the silicon channel, thereby overcoming the scaling limitation shown in the silicon channel.

Accordingly, various methods of forming a 2D channel layer using a 2D material have been studied, and some have been introduced, but various problems (e.g., channel damage, change in physical properties, etc.) may appear in the manufacturing process.

### SUMMARY

Provided are methods of manufacturing a 2D channel layer capable of preventing the 2D channel layer from growing in a random direction.

Alternatively or additionally, provided are methods of manufacturing a 2D channel layer capable of defining a channel in a desired shape.

Alternatively or additionally, provided are layer structures including a 2D channel layer formed using the methods described above.

Alternatively or additionally, provided are electronic devices including the layer structure.

Alternatively or additionally, provided are electronic apparatuses including the electronic device.

Additional aspects will be set forth in part in the description which follows and, in part, will be apparent from the description, or may be learned by practice of the presented embodiments of the present disclosure.

According to an embodiment, a layer structure may include a first substrate, a second substrate surrounded by the first substrate, and a two-dimensional (2D) channel layer on the second substrate. An interfacial energy of the second substrate may be less than an interfacial energy of the first substrate.

In some examples, the first substrate may include a trench, and the second substrate may be in the trench. In some examples, the second substrate may be along a surface of the trench, and the 2D channel layer may be along a surface of the second substrate. In some examples, the 2D channel layer may fill the trench in the first substrate.

In some examples, the second substrate may completely fill the trench. In some examples, the second substrate may completely fill the trench and an upper surface of the second substrate may be higher than an upper surface of the first substrate.

In some examples, the trench may be a step type trench including portions having different widths, and the first substrate and the second substrate may have a same height.

In some examples, the first substrate and the second substrate may have a same height.

In some examples, the second substrate may have a fin shape and may protrude in a direction perpendicular to a surface of the first substrate.

In some examples, the 2D channel layer may include a 2D semiconductor material layer.

According to an embodiment, an electronic device may include one of the layer structures above and a plurality of electrode layers on the layer structure. The first substrate may be a substrate. The two-dimensional (2D) channel layer on the second substrate may be on the substrate. The plurality of electrode layers may include a first electrode layer and a second electrode layer separated from each other on the 2D channel layer. The plurality of electrode layers may further include a third electrode layer on the 2D channel layer between the first electrode layer and the second electrode layer, and the third electrode layer may be spaced part from the 2D channel layer.

According to an embodiment, an electronic apparatus may include the electronic device.

According to an embodiment, a memory device may include a switching device; and a data storage element connected to the switching device. The switching device may include one of the layer structures above.

According to an embodiment, an electronic apparatus may include the memory device.

According to an embodiment, a method of manufacturing a 2D channel layer may include forming a first substrate; forming a second substrate surrounded by the first substrate, forming a precursor layer on one of the first substrate and the second substrate, the precursor layer for forming a 2D channel; and transforming the precursor layer into a liquid precursor layer. An interfacial energy of the second substrate may be less than an interfacial energy of the first substrate.

In some examples, the forming the second substrate surrounded by the first substrate may include forming a trench in the first substrate, and forming the second substrate in the trench.

In some examples, the trench may be a step type trench including portions having different widths.

In some examples, the forming the second substrate in the trench may include completely filling the trench with the second substrate.

In some examples, the forming the second substrate may include forming the second substrate along a surface of the trench such that the second substrate does not completely fill the trench.

In some examples, the forming the second substrate may include forming the second substrate at a same height as the first substrate.

In some examples, the second substrate may be formed to have a fin shape in a direction perpendicular to the first substrate.

In some examples, the second substrate may include a main substrate and an auxiliary substrate. The auxiliary substrate may be connected to the main substrate. An area of the auxiliary substrate may be smaller than an area of the main substrate. The auxiliary substrate may include a first portion and a second portion. The first portion of the auxiliary substrate may have a constant width. The second portion of the auxiliary substrate may be between the main substrate and the first portion of the auxiliary substrate. A portion of the second portion of the auxiliary substrate may be directly connected to the main substrate. A width of the portion of the second portion of the auxiliary substrate may be narrower than a width of the first portion of the auxiliary substrate. The forming the precursor layer may form the precursor layer on the auxiliary substrate. The method optionally may include forming a 2D channel layer on the main substrate.

In some examples, the forming the precursor layer may include any one of forming the precursor layer on a partial region of the second substrate, forming the precursor layer on a region including a boundary between the first substrate and the second substrate and a portion of the first substrate and the second substrate on both sides of the boundary, and forming the precursor layer on a partial region of the first substrate in contact with the boundary.

In some examples, the second substrate may be formed in a same shape as a planar shape of a 2D channel layer to be formed.

### BRIEF DESCRIPTION OF THE DRAWINGS

The above and other aspects, features, and advantages of certain example embodiments of the disclosure will be more apparent from the following description taken in conjunction with the accompanying drawings, in which:

FIGS. 1 to 10D are cross-sectional views and plan views illustrating a method of manufacturing a two-dimensional (2D) semiconductor material layer, according to some example embodiments;

FIG. 11 is a plan view illustrating a method of manufacturing a 2D semiconductor material layer, according to some example embodiments;

FIGS. 12 to 25 are plan views and cross-sectional views showing a first embodiment of a method of manufacturing a 2D semiconductor material layer along a surface of a three-dimensional (3D) structure according to some example embodiments;

FIGS. 26 to 31 are plan views and cross-sectional views showing a second embodiment of a method of manufacturing a 2D semiconductor material layer along a surface of a 3D structure according to some example embodiments;

FIG. 32 is a cross-sectional view illustrating a first electronic device according to some example embodiments;

FIG. 33 is a cross-sectional view illustrating a modification of the first electronic device of FIG. 32;

FIG. 34 is a 3D view illustrating a second electronic device according to some example embodiments;

FIG. 35 is a cross-sectional view illustrating a third electronic device according to some example embodiments;

FIG. 36 is a schematic block diagram of a display driver IC (DDI) and a display device including the DDI as a first electronic apparatus according to some example embodiments;

FIG. 37 is a block diagram illustrating an electronic system as a second electronic apparatus according to some example embodiments;

FIG. 38 is a block diagram of an electronic system as a third electronic apparatus according to some example embodiments; and

FIG. 39 is a block diagram showing a configuration of a fourth electronic apparatus according to some example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, a layer structure including a two-dimensional (2D) channel layer and a method of manufacturing the same according to some example embodiments, an electronic device including a 2D channel layer formed by this method, and an electronic apparatus including the electronic device will be described in detail with reference to the accompanying drawings.

In the drawings, thicknesses of layers and regions may be exaggerated for clarification of the specification. Embodiments of inventive concepts are capable of various modifications and may be embodied in many different forms. When an element or layer is referred to as being “on” or “above” another element or layer, the element or layer may be directly on another element or layer or intervening elements or layers. In the following descriptions, like reference numerals refer to like elements.

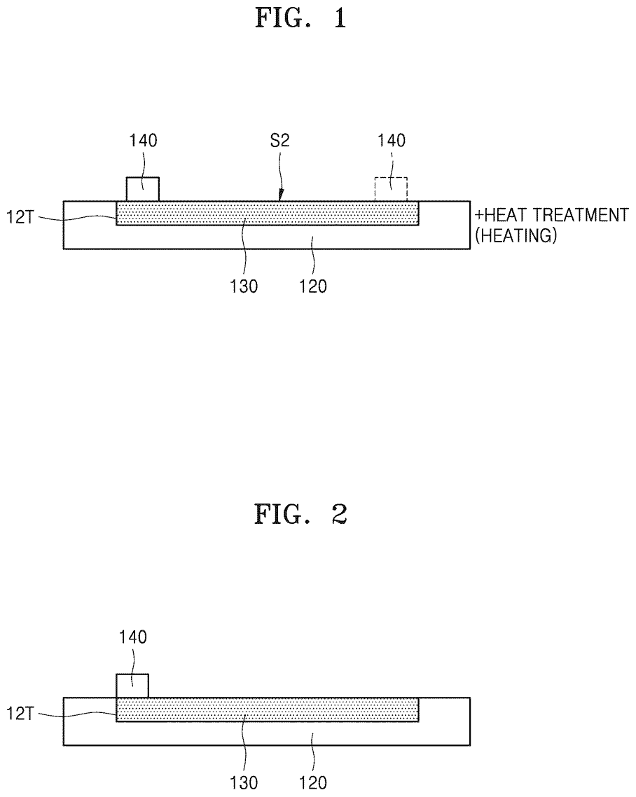

FIGS. 1 to 10D are cross-sectional views and plan views illustrating a method of manufacturing a two-dimensional (2D) semiconductor material layer, according to some example embodiments.

Referring to FIG. 1, a second substrate 130 is formed on a first substrate 120. The second substrate 130 may be formed to be partially buried in the first substrate 120. For example, a trench 12T for forming the second substrate 130 may be formed in the first substrate 120, and the second substrate 130 may be formed to substantially and completely fill the trench 12T. A bottom surface of the trench 12T may be substantially flat, but is not limited thereto. For example, the bottom surface of the trench 12T may be substantially parallel to a bottom surface of the first substrate 120, but may not be the case.

The entire one surface S2 of the second substrate 130 may be exposed and the surface S2 may be not buried. The one surface S2 may be an upper surface of the second substrate 130, but may also be a bottom surface, a side surface, or an inclined surface according to the viewpoint of FIG. 1. A height of one surface S2 of the second substrate 130 may be substantially the same as a height of the upper surface of the first substrate 120 around the second substrate 130.

Interfacial energy of the first substrate 120 and interfacial energy of the second substrate 130 may be different from each other. For example, the interfacial energy of the second substrate 130 may be less than the interfacial energy of the first substrate 120. In other words, the interfacial energy of the second substrate 130 may be lower than the interfacial energy of the first substrate 120. Materials of the first and second substrates 120 and 130 may satisfy the interfacial energy condition. In an example, the first substrate 120 may be a first insulating substrate including at least one insulating layer, and may include one selected from a group of insulating materials including a plurality of insulating materials. In some examples, the second substrate 130 may be a second insulating substrate, and may include an insulating material having surface energy less than that of the first substrate 120 from among the group of insulating materials. In some examples, the insulating material group may include, but is not limited to, metal oxide, parylene-C, an organic material including polyimide, SiO₂, a ceramic material, or silicon (Si). In some examples, the metal oxide may include, but is not limited to, aluminum oxide and hafnium oxide. In some examples, the aluminum oxide may include Al₂O₃, but is not limited thereto.

In some examples, the second substrate 130 may be formed using a deposition method, such as a Chemical Vapor Deposition (CVD) method, a Physical Vapor Deposition (PVD) method, an Atomic Layer Deposition (ALD) method, a sputtering method, etc. or may be formed by an epitaxy method, but the methods are not limited thereto.

After the second substrate 130 is formed, a precursor layer 140 is formed on a partial region of the second substrate 130. The precursor layer 140 may be formed to be biased toward one side of the second substrate 130, and a region of the second substrate 130 on which the precursor layer 140 is formed may be preset. In some examples, the precursor layer 140 may be formed near the left side of the second substrate 130, but may be formed near the right side of the second substrate 130 as indicated by a dotted line box, but is not limited thereto. As an example, the precursor layer 140 may be formed near an edge of the second substrate 130 on the one surface S2 of the second substrate 130. In some examples, the precursor layer 140 may include a precursor material for forming a 2D semiconductor material layer. In some examples, the precursor layer 140 may include a material that may be liquefied at a relatively low temperature (e.g., a temperature of about 500° C.). For example, the precursor layer 140 may include a transition metal. In some examples, the precursor layer 140 may include a mixture of a transition metal and an alkali metal. In some examples, the precursor layer 140 may include one or more kinds of elements constituting the 2D semiconductor material layer. For example, the precursor layer 140 has a form of (Na)ₓ(Mo)_{y}(O)_{z} (x≥0, y>0, and z>0), and may include alkali metals, such as Li, K, etc., in addition to Na. For example, the precursor layer 140 may include at least one of Na₂MoO₄, Na₂Mo₂O₇, K₂MoO₄, and LiMoO₄. In some examples, the precursor layer 140 may include at least one selected from a metal oxide, such as MoO₃, a metal, such as Mo, ammonium molybdate, such as (NH₄)₂MoO₄, molybdenum oxychloride, such as MoOCl₄, molybdenum chloride, such as MoCl₆, and molybdenum hexacarbonyl, such as Mo(CO)₆, or may include a mixture in which the selected one is mixed with one or more selected from alkali metal halides, such as NaCl.

In some examples, the precursor layer 140 may be formed by a photolithography process in which a deposited material film is patterned after depositing the material film. In some examples, the precursor layer 140 may be formed by an inkjet method, for example, may be formed by dropping volatile liquid droplets including a precursor material on a desired and/or alternatively predetermined position of the second substrate 130. After the volatile liquid droplets are dropped on the second substrate 130, the liquid may be volatilized from the droplets, and only the precursor material may remain on the second substrate 130.

After the precursor layer 140 is formed, a subsequent process (e.g., a heat treatment process) for liquefying the precursor layer 140 may be performed.

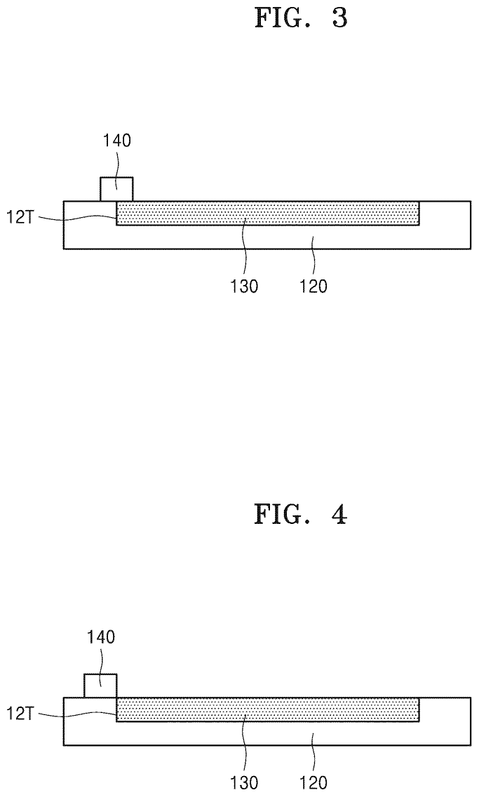

In an example, as shown in FIG. 2, the precursor layer 140 may be formed on the second substrate 130, but may be formed by being attached to a boundary between the first and second substrates 120 and 130. In some examples, the precursor layer 140 may be formed on the boundary between the first substrate 120 and the second substrate 130 as shown in FIG. 3. In this case, the precursor layer 140 may also be formed on a portion of the second substrate 130 on the right side of the boundary and on a portion of the first substrate 120 on the left side of the boundary. That is, the precursor layer 140 may be formed on a boundary between the first and second substrates 120 and 130 and a region including a portion of the first substrate 120 and a portion of the second substrate 130 on both sides of the boundary.

In some examples, the precursor layer 140 may be formed on the first substrate 120 as shown in FIG. 4. In this case, the precursor layer 140 may be formed to adhere to the boundary between the first substrate 120 and the second substrate 130.

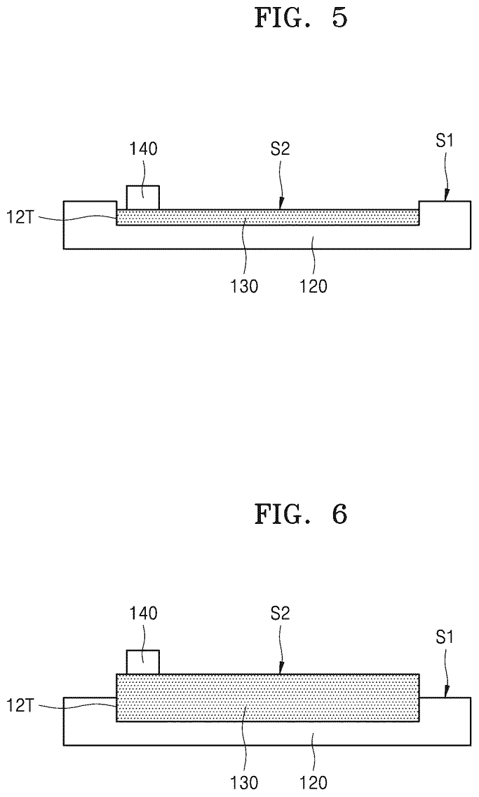

In some examples, as shown in FIG. 5, the one surface S2 of the second substrate 130 may be lower than an upper surface S1 of the adjacent first substrate 120. For example, in a process of forming the second substrate 130 in the trench 12T formed in the first substrate 120, the second substrate 130 may be formed lower than the upper surface S1 of the first substrate 120.

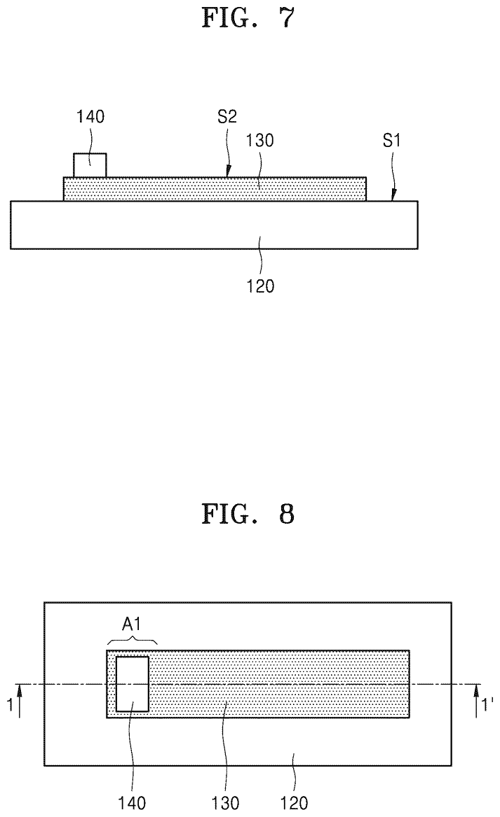

In some examples, the one surface S2 of the second substrate 130 may be higher than the upper surface S1 of the first substrate 120 as shown in FIG. 6 or FIG. 7.

Referring to FIG. 6, in the process of forming the second substrate 130 in the trench 12T of the first substrate 120, the one surface S2 of the second substrate 130 may be formed higher than the trench 12T, that is, may be formed higher than the upper surface S1 of the first substrate 120.

In some examples, as shown in FIG. 7, when the first substrate 120 does not have a concave portion, such as the trench 12T and the entire upper surface S1 is flat, the second substrate 130 may be formed on a partial region of the upper surface S1 of the first substrate 120, that is, on a region where a channel is to be formed on the upper surface S1 of the first substrate 120.

In the cases of FIGS. 5 to 7, because the upper surface S1 of the first substrate 120 is higher or lower than the one surface S2 of the second substrate 130, a step difference is formed between the upper surface S1 of the first substrate 120 and the one surface S2 of the second substrate 130.

FIG. 8 is a plan view of FIG. 1. FIG. 1 may be a cross-sectional view taken along line 1-1′ of FIG. 8. In some examples, FIG. 8 may be a plan view of FIGS. 5 to 7, and FIGS. 5 to 7 may be a cross-sectional view taken along the line 1-1′ of FIG. 8. In FIG. 8, reference numeral A1 denotes a region where the precursor layer 140 is formed.

As depicted in FIG. 1, after the precursor layer 140 is formed, a process of liquefying the precursor layer 140 (hereinafter, a precursor layer liquefaction process) may be performed. In some examples, the precursor layer liquefaction process may include a process of heat-treating or heating a resultant product on which the precursor layer 140 is formed in a set temperature range, but is not limited thereto. In some examples, the heat treatment or heating may be carried out at a temperature in a range from about 100° C. to about 1000° C.

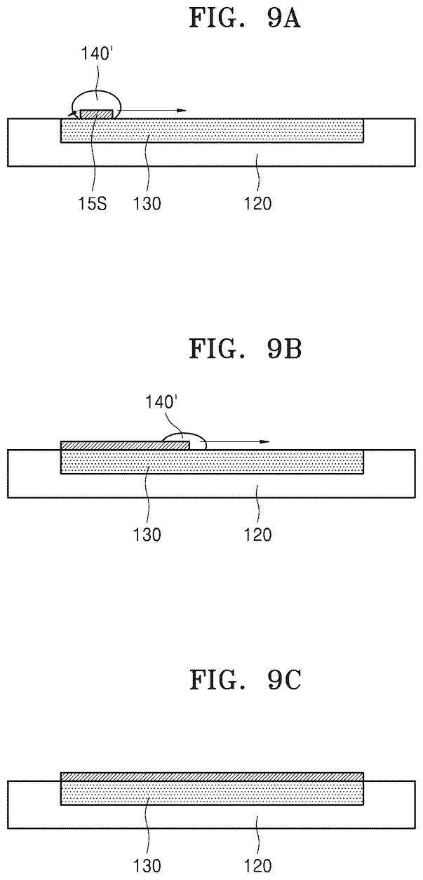

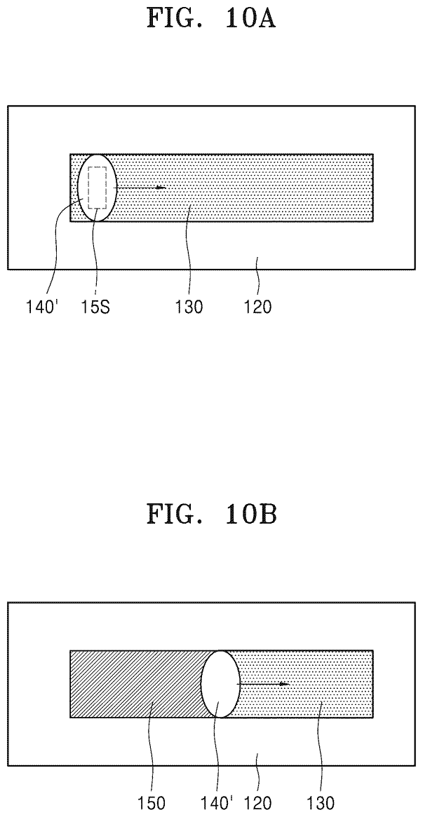

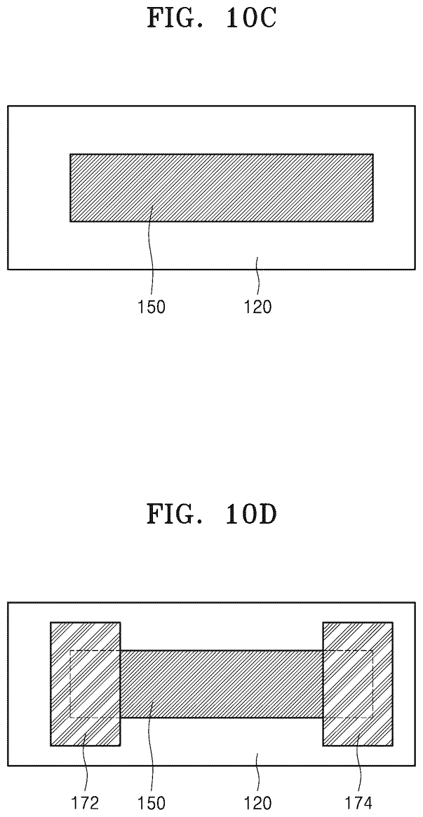

FIGS. 9A to 9C are cross-sectional views showing a process of forming a 2D semiconductor material layer by flowing a precursor layer 140′ (hereinafter, a liquid precursor layer) liquefied by the precursor layer liquefaction process onto the second substrate 130, and FIGS. 10A to 10D are plan views thereof.

Referring to FIGS. 9A and 10A, as the precursor layer 140 is liquefied, initially a seed of a 2D semiconductor material layer or a seed layer 15S is formed at a bottom of the liquid precursor layer 140′, that is, an upper surface of the second substrate 130, and the liquid precursor layer 140′ covers the seed layer 15S and is in contact with the second substrate 130 around the seed layer 15S. The liquid precursor layer 140′ may completely cover the seed layer 15S.

Because the interfacial energy of the second substrate 130 is less than the interfacial energy of the first substrate 120, the liquid precursor layer 140′ flows onto the second substrate 130 having a relatively low interfacial energy. Due to the characteristic of the liquid precursor layer 140′, the liquid precursor layer 140′ may selectively flow only on the second substrate 130. On the second substrate 130, the liquid precursor layer 140′ may flow in all directions of the seed layer 15S. In this process, the liquid precursor layer 140′ may be in a selected gas atmosphere depending on the material components included in the liquid precursor layer 140′. For example, when the liquid precursor layer 140′ includes molybdenum (Mo) as one component of the 2D semiconductor material layer, the liquid precursor layer 140′ may be in a sulfur (S) gas atmosphere.

As shown in FIGS. 9B, 9C, 10B, and 10C, due to the selectivity of the liquid precursor layer 140′, as the liquid precursor layer 140′ moves to the right of the seed layer 15S, the seed layer 15S also expands or grows to the right. As a result, a 2D semiconductor material layer 150 is directly formed on the second substrate 130. That is, the entire upper surface of the second substrate 130 is covered with the 2D semiconductor material layer 150. Due to the selectivity of the liquid precursor layer 140′, the 2D semiconductor material layer 150 is not formed on the first substrate 120. The 2D semiconductor material layer 150 may be various material layers depending on the material used as the precursor layer 140. In some examples, the 2D semiconductor material layer 150 may include transition metal dichalcogenide (TMD), but is not limited thereto. In some examples, the 2D semiconductor material layer 150 may include MoS₂, WS₂, MoSe₂, or WSe₂. In some examples, the 2D semiconductor material layer 150 may be a single layer or a multilayer. For example, the 2D semiconductor material layer 150 may be formed to form a layered structure in which several or tens of single layers are stacked. In some examples, the layered structure may include about 1 to 10 or about 1 to 5 single layers of 2D semiconductor material. In some examples, the process of forming the 2D semiconductor material layer 150 may be repeated two or more times. In this way, a thickness of the 2D semiconductor material layer 150 may be increased.

Because the difference between the interfacial energy of the liquid precursor layer 140′ and the interfacial energy of the second substrate 130 is substantially constant and the interfacial energy difference between the first and second substrates 120 and 130 is also substantially constant, the moving speed of the liquid precursor layer 140′ on the substrate 130 may be substantially constant. Accordingly, the thickness of the 2D semiconductor material layer 150 may be substantially uniform over the entire upper surface of the second substrate 130.

As described above, the 2D semiconductor material layer 150 may be formed to have a substantially constant thickness, and may be formed only on the second substrate 130. Accordingly, the 2D semiconductor material layer 150 may be formed in various forms depending on the shape of the second substrate 130. For example, when a planar shape of the second substrate 130 is a straight line shape, the 2D semiconductor material layer 150 may also be formed in a straight line shape having a substantially constant thickness. For example, if the planar shape of the second substrate 130 is a straight line shape, but has portions having different widths, the 2D semiconductor material layer 150 may also be formed in the same shape while having a substantially constant thickness. In some examples, as described below, when the second substrate 130 has a 3D shape, that is, a stereoscopic shape, the 2D semiconductor material layer 150 will be formed on the surface of the second substrate 130, and thus, the 2D semiconductor material layer 150 may form a 3D structure having a substantially uniform thickness.

Therefore, when the 2D semiconductor material layer 150 is applied to a plurality of the same electronic devices (e.g., field effect transistors, optical devices, etc.), for example, when the 2D semiconductor material layer 150 is used as a channel (active layer) of the electronic devices, the channels (active layers) of all of the electronic devices may have substantially the same shape and the same thickness. Accordingly, because the electronic devices may have substantially the same threshold voltage and exhibit substantially the same operating characteristics under the same operating conditions, the operational reliability of the electronic devices may be increased.

Meanwhile, the amount of the liquid precursor layer 140′ may be determined considering a size of a region where the 2D semiconductor material layer is formed, for example, an area of the upper surface of the second substrate 130. When the amount of the liquid precursor 140′ is determined, the size, volume, or bulk of the precursor layer 140 may be determined. The required size of the precursor layer 140 or the amount of the liquid precursor layer 140′ may vary depending on the material used for the precursor layer 140, that is, the material of the precursor layer 140. In addition, the mobility or movement speed of the liquid precursor layer 140′ may be adjusted according to physical properties of the liquid precursor layer 140′, chemical properties of the liquid precursor layer 140′ and/or an interfacial energy difference between the liquid precursor layer 140′ and the second substrate 130. For example, as the liquid precursor layer 140′ is sensitive to the interfacial energy difference, the mobility or movement speed of the liquid precursor layer 140′ may increase.

After the 2D semiconductor material layer 150 is selectively formed only on the second substrate 130, as shown in FIG. 10D, first and second electrode layers 172 and 174 may be formed on the 2D semiconductor material layer 150. The first and second electrode layers 172 and 174 are separated from each other. The first electrode layer 172 may be formed to cover the left side of the 2D semiconductor material layer 150, and the second electrode layer 174 may be formed to cover the right side of the 2D semiconductor material layer 150. A portion between the first and second electrode layers 172 and 174 in the 2D semiconductor material layer 150, that is, a portion connecting the first electrode layer 172 and the second electrode layer 174 is used as a channel. The channel may be expressed as a channel layer.

The channel may be a passage through which carriers, such as electrons, move. A control layer or a control electrode for checking the movement of the carriers may be provided on the channel so as not to directly contact the channel. In some examples, one of the first and second electrode layers 172 and 174 may be a source electrode of a field effect transistor, and the other may be a drain electrode. In some examples, the control layer or the control electrode may be a gate electrode of a field effect transistor.

FIG. 11 shows a method of manufacturing a 2D semiconductor material layer, according to some example embodiments. Like reference numbers as the aforementioned reference numbers indicate like members, and a description thereof will be omitted.

Referring to FIG. 11, a second substrate 230 is formed on a first substrate 120. The material of the second substrate 230 may be the same as that of the second substrate 130 described with reference to FIGS. 1 to 10D. The second substrate 230 includes a main substrate 230A and an auxiliary substrate 230B connected to each other to form a single body. The main and auxiliary substrates 230A and 230B are a continuum of the same material, and there is no physical boundary between the main substrate 230A and the auxiliary substrate 230B. The main substrate 230A is a portion on which a 2D semiconductor material layer is to be formed in a subsequent process, and has a greater area than the auxiliary substrate 230B. A precursor layer 140 is formed on the auxiliary substrate 230B. The auxiliary substrate 230B may have a shape so that the 2D semiconductor material layer to be formed on the main substrate 230A is formed as a single crystal material layer. For example, the auxiliary substrate 230B may include a first portion P1 having a constant width in a first direction (e.g., an x-axis direction) and a second portion P2 having a width gradually decreasing in the first direction. The second portion P2 is between the first portion P1 and the main substrate 230A, and the width of the second portion P2 narrows towards the main substrate 230A.

The precursor layer 140 may be formed on the first portion P1. As described with reference to FIGS. 9A to 10D, as the precursor layer 140 is transformed into the liquid precursor layer 140′, a 2D semiconductor material layer is selectively formed only on the second substrate 230, and at this time, the 2D semiconductor material layer is sequentially formed on the first portion P1 and the second portion P2, and the 2D semiconductor material layer formed in the second portion P2 extends onto the main substrate 230A through a portion where the width of the second portion P2 is narrowest. Due to the characteristic that the width of the second portion P2 gradually narrows, a seed of the 2D semiconductor material formed on the auxiliary substrate 230B is limited to extend onto the main substrate 230A while the precursor layer 140 is liquefied. Accordingly, the 2D semiconductor material layer formed on the main substrate 230A may be formed in a single crystal state.

Although the second portion P2 is formed in a shape in which the width is gradually reduced, the second portion P2 may be patterned in a different shape while maintaining the same operating characteristics. For example, the second portion P2 may have a constant width, but may be formed to have a width narrower than that of the first portion P1.

The method of manufacturing the 2D semiconductor material layer illustrated in FIGS. 1 to 11, that is, the method of manufacturing a 2D channel, may be applied to a three-dimensional (3D) structure. In other words, the first substrate 120 or the second substrate 130 may be formed to include a 3D structure or may be formed to have a 3D structure, and a 2D semiconductor material layer may be formed along a surface of the 3D structure.

FIGS. 12 to 25 show various examples of cases in which a 2D channel is formed in a trench structure as a first embodiment.

FIG. 12 is a plan view showing a resultant product in which a second substrate 330 covering the trench 13T is formed on the first substrate 320 in which the trench 13T is formed, and a precursor layer 340 is formed on a partial region of the second substrate 430.

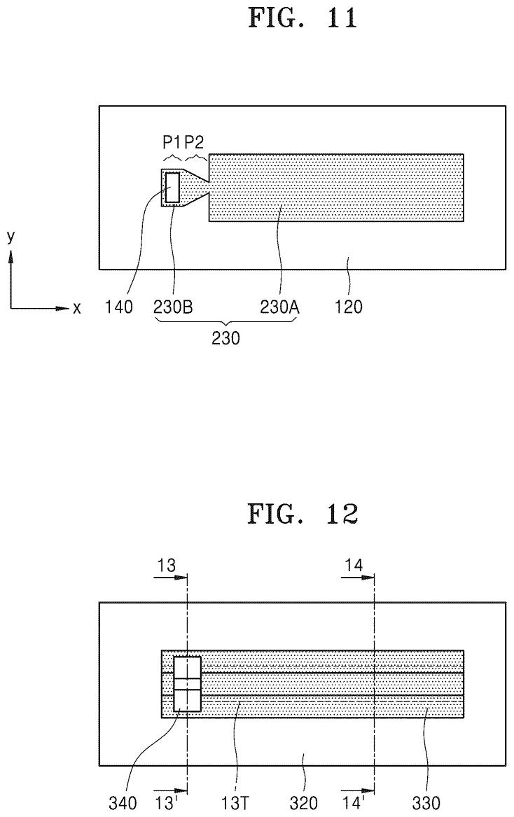

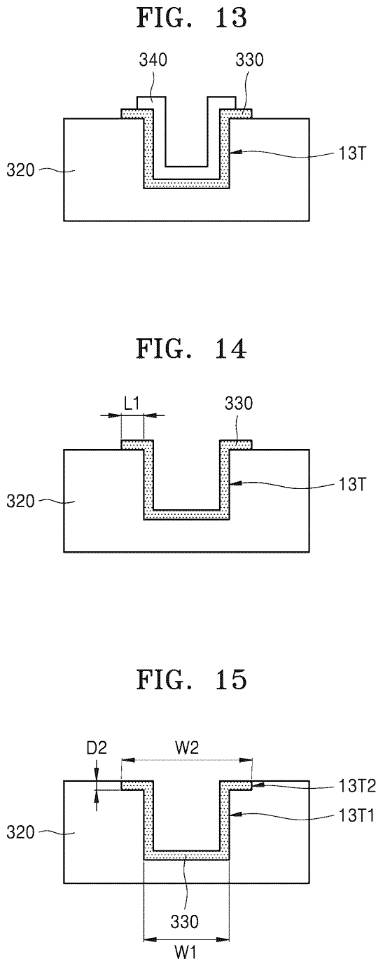

FIG. 13 is a cross-sectional view taken along line 13-13′ of FIG. 12. FIG. 14 is a cross-sectional view taken along line 14-14′ of FIG. 12.

Referring to FIGS. 12 to 14, the trench 13T is formed in the first substrate 320, and the second substrate 330 is formed on the first substrate 320 to cover a surface of the trench 13T. That is, the second substrate 330 may be directly formed on a bottom and side surfaces of the trench 13T, and may cover the entire bottom and side surfaces of the trench 13T. The second substrate 330 may be formed along the bottom and side surfaces of the trench 13T, but is not formed to completely fill the trench 13T. In some examples, the second substrate 330 may be formed to partially fill the trench 13T, and may be formed to fill half of the trench 13T or fill the trench 13T to half or less. The second substrate 330 may extend on an upper surface of the first substrate 320 around the trench 13T in a direction perpendicular to a depth of the trench 13T.

The depth and width of the trench 13T may be determined considering a material layer formed or filled in the trench 13T and a degree of filling the trench 13T.

A material of the first substrate 320 may be the same as that of the first substrate 120 described above. A material of the second substrate 330 may be the same as that of the second substrate 130 described above.

As described with reference to FIGS. 1 to 11, a shape of the 2D semiconductor material layer formed in a subsequent process, that is, the 2D channel, may be determined according to the shape of the second substrate 330 in that the 2D semiconductor material layer is selectively formed only on a substrate having low interfacial energy. The second substrate 330 may be formed considering this point.

The precursor layer 340 is formed on a partial region of the second substrate 330. The precursor layer 340 may be formed to one side of the second substrate 330, for example, as shown in FIG. 12, the precursor layer 340 may be formed near a left end of the second substrate 330. In some examples, the precursor layer 340 may be formed near a right end of the second substrate 330. The material and method of manufacturing the precursor layer 340 may be the same as those of the precursor layer 140 described with reference to FIGS. 1 to 11.

Referring to FIG. 13, the precursor layer 340 is formed along a surface of the second substrate 330 in the trench 13T. The precursor layer 340 is formed to cover inner side surfaces and a bottom upper surface of the second substrate 330. In addition, the precursor layer 340 may extend even on an upper surface of a portion of the second substrate 330 that extends onto the first substrate 320. The precursor layer 340 is formed along the surface of the second substrate 330, but is not formed to fill the trench 13T like the second substrate 330. In some examples, the precursor layer 340 may be formed to fill the trench 13T in which the second substrate 330 is formed, but even in this case, the precursor layer 340 may be formed to fill half or less than half of the trench 13T.

In FIGS. 13 and 14, the second substrate 330 extends on the upper surface of the first substrate 320 on both sides of the trench 13T. Accordingly, a step difference is formed between the upper surface of the extended portion of the second substrate 330 and the upper surface of the first substrate 320.

In some examples, the extended portion of the second substrate 330 may be formed to be flush with the upper surface of the first substrate 320, as shown in FIG. 15.

Referring to FIG. 15, the first substrate 320 includes a first trench 13T1 and a second trench 13T2. The second trench 13T2 is formed above the first trench 13T1 and is connected to the first trench 13T1 as one. The second trench 13T2 is formed on an entrance side of the first trench 13T1, and a width W2 of the second trench 13T2 is greater than a width W1 of the first trench 13T1. Accordingly, a step difference is formed between the first and second trenches 13T1 and 13T2. Consequently, the first and second trenches 13T1 and 13T2 are combined to form a one step-type trench.

A depth D2 of the second trench 13T2 may correspond to a thickness of the expanded portion of the second substrate 330. In addition, a difference W2−W1 between the width W2 of the second trench 13T2 and the width W1 of the first trench 13T1 may correspond to a length L1 of the extended portion of the second substrate 330.

Accordingly, while the expanded portion of the second substrate 330 fills the second trench 13T2 around the first trench 13T1, the upper surface of the expanded portion of the second substrate 330 forms the same surface as the upper surface of the first substrate 320. In other words, a height of the expanded portion of the second substrate 330 is equal to a height of the upper surface of the first substrate 320.

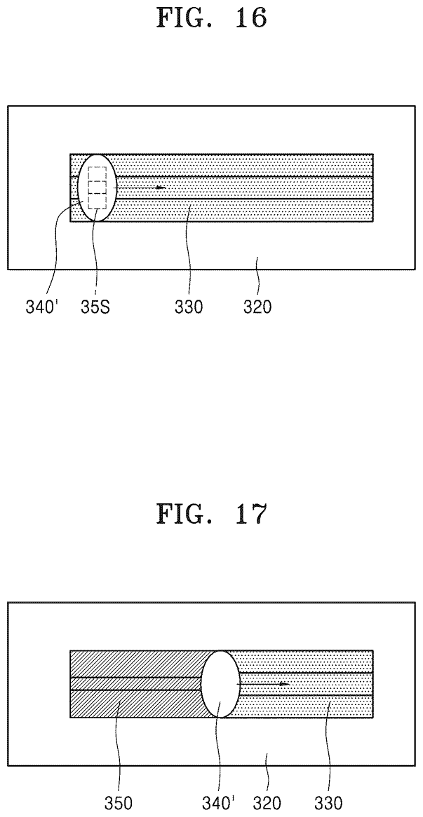

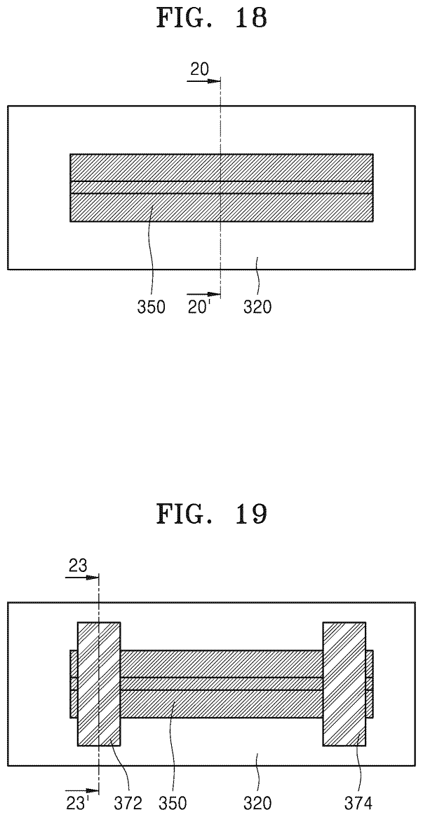

As shown in FIGS. 12 and 13, after the precursor layer 340 is formed on the second substrate 330, as shown in FIG. 16, a liquid precursor layer 340′ is formed in a place where the precursor layer 340 was placed by liquefying the precursor layer 340. As the liquid precursor layer 340′ is formed, a seed layer 35S is also formed in the same place. As the liquid precursor layer 340′ is moved onto the second substrate 330 having a relatively low interfacial energy, the seed layer 35S also extends onto the second substrate 330, and as shown in FIGS. 17 and 18, the 2D semiconductor material layer 350 is selectively formed only on the second substrate 330. This process may be performed according to a process of forming the liquid precursor layer 140′ described with reference to FIGS. 9A to 10D and forming the 2D semiconductor material layer 150 according to the movement thereof.

After the semiconductor material layer 350 is formed on the surface of the second substrate 330, for example, on the entire side and bottom upper surfaces of the second substrate 330 formed in the trench 13T and the entire upper surface of the expanded portion of the second substrate 330, as shown in FIG. 19, a first electrode layer 372 and a second electrode layer 374 may be formed on the 2D semiconductor material layer 350. The first and second electrode layers 372 and 374 are separated from each other. The arrangement and roles of the first and second electrode layers 372 and 374 may be the same as those of the first and second electrode layers 172 and 174 described with reference to FIG. 10D. In addition, a control layer or a control electrode described with reference to FIG. 10D may be formed on the 2D semiconductor material layer 350 between the first and second electrode layers 372 and 374.

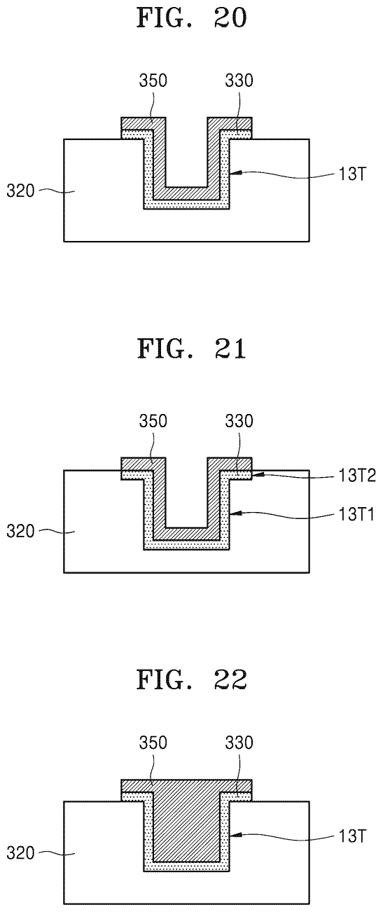

FIG. 20 is a cross-sectional view taken along line 20-20′ of FIG. 18.

Referring to FIG. 20, a 2D semiconductor material layer 350 is formed along a surface of the second substrate 330. The 2D semiconductor material layer 350 covers all of side and bottom surfaces of the second substrate 330 in the trench 13T, and covers a portion of an entire upper surface of the second substrate 330 extending onto the first substrate 320.

FIG. 21 shows a case in which the 2D semiconductor material layer 350 is formed on the second substrate 330 when the first substrate 320 and the second substrate 330 in FIG. 20 have the structures described with reference to FIG. 15.

Comparing FIG. 20 to FIG. 21, the formation position of the 2D semiconductor material layer 350 with respect to the second substrate 330 in FIG. 21 may be the same as described with reference to FIG. 20.

As depicted in FIGS. 20 and 21, the 2D semiconductor material layer 350 may be formed to have a substantially constant thickness along the surface of the trench 13T, and may be formed in a shape that does not fill the trench 13T. In some examples, as shown in FIG. 22, the trench 13T may be completely filled with the 2D semiconductor material layer 350.

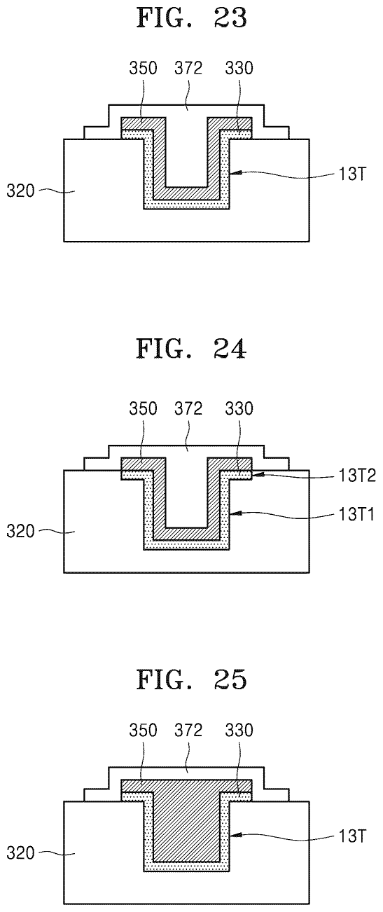

FIG. 23 shows a cross-sectional view taken along line 23-23′ of FIG. 19.

Referring to FIG. 23, the first electrode layer 372 fills the trench 13T in which the 2D semiconductor material layer 350 is formed, and covers the 2D semiconductor material layer 350 and the second substrate 330.

In FIG. 23, the first substrate 320, the second substrate 330, and the 2D semiconductor material layer 350 may have a layer structure as shown in FIG. 21, and FIG. 24 shows an example thereof.

Also, in FIG. 23, the first substrate 320, the second substrate 330, and the 2D semiconductor material layer 350 may have a layer structure as shown in FIG. 22, and FIG. 25 shows an example thereof.

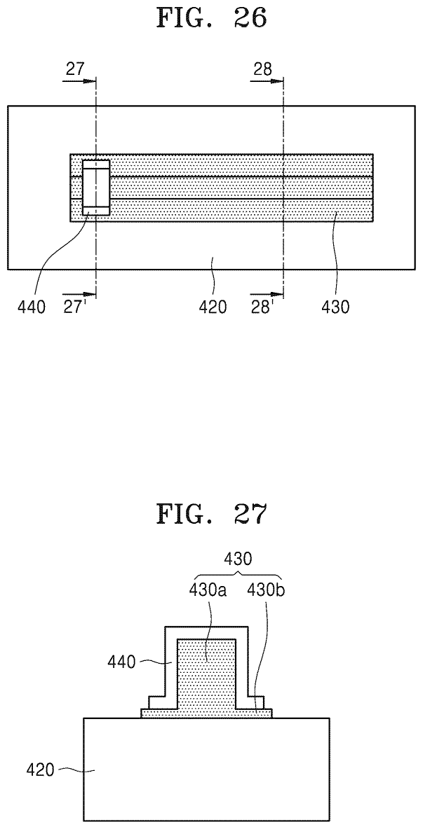

As a second embodiment of a case in which a 2D semiconductor material layer is formed along the surface of a 3D structure, FIGS. 26 to 31 show various examples of a case in which a 2D channel is formed in a 3D structure in a fin shape according to the method of manufacturing the 2D semiconductor material layer illustrated in FIGS. 1 to 11, that is, the method of manufacturing a 2D channel.

FIG. 26 is a plan view of a resultant product in which a second substrate 430 having a fin shape is formed on the first substrate 420 and a precursor layer 440 is formed on a partial region of the second substrate 430.

FIG. 27 is a cross-sectional view taken along line 27-27′ of FIG. 26.

Referring to FIG. 27, the second substrate 430 is formed in a 3D structure on one surface of the first substrate 420. The one surface of the substrate 420 may be an upper surface, but may also be a lower surface, a side surface, or an inclined surface depending on the viewpoint.

The second substrate 430 includes a vertical portion 430a and a horizontal portion 430b having a height less than that of the vertical portion 430a. Although it is divided into the vertical part 430a and the horizontal part 430b for structure description, the second substrate 430 may be a single body in which the vertical part 430a and the horizontal part 430b are connected to each other. Therefore, there is no boundary or boundary line that may be physically divided between the vertical portion 430a and the horizontal portion 430b. The vertical portion 430a has a fin shape and is formed in a direction perpendicular to the one surface of the first substrate 420. An aspect ratio of the vertical portion 430a may be 1 or greater than 1, but may be less than 1 in a state in which the second substrate 430 maintains a 3D structure. The horizontal portion 430b is parallel to the one surface of the first substrate 420. A width of the horizontal portion 430b in a direction parallel to the one surface of the first substrate 420 may be greater than a width of the vertical portion 430a.

A shape of the 2D semiconductor material layer formed in a subsequent process also varies according to the shape of the second substrate 430. Accordingly, the shape of the second substrate 430 may be a major factor in defining or determining the shape or structure of the 2D semiconductor material layer. Therefore, when the 2D semiconductor material layer is used as a channel through which carriers (e.g., electrons) move, the shape or structure of the channel may be determined while the second substrate 430 is formed in a specific shape or structure. For example, when the second substrate 430 has a fin shape as described above, an outer shape of the 2D semiconductor material layer to be formed on the second substrate 430 may also have a fin shape.

Materials of the first and second substrates 420 and 430 may be the same as those of the first and second substrates 120 and 130 described above.

A precursor layer 440 is formed on the second substrate 430. A material and liquefaction characteristics of the precursor layer 440 may be the same as those of the precursor layer 140 described above. The precursor layer 440 covers entire side surfaces and an upper surface of the vertical portion 430a of the second substrate 430. The precursor layer 440 also extends over an upper surface of the horizontal portion 430b. Because the precursor layer 440 is formed in such a shape, an outer shape of the precursor layer 440 may be a fin shape like the second substrate 430.

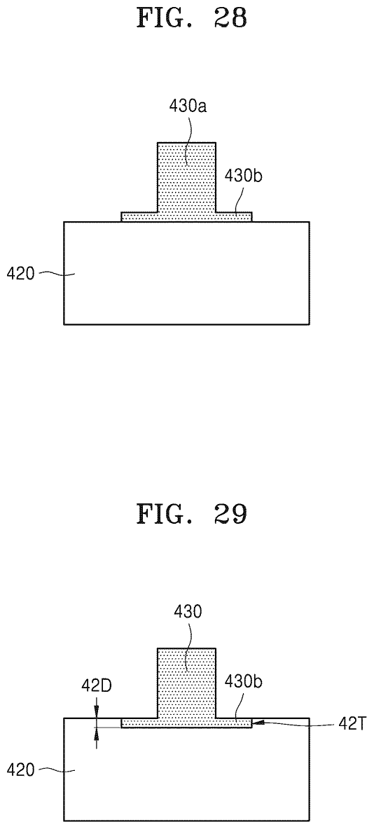

FIG. 28 shows a cross-sectional view taken along line 28-28′ of FIG. 26. The cross-section shown in FIG. 28 is the same as remaining portions except for the precursor layer 440 in FIG. 27.

In FIGS. 27 and 28, a flat portion, that is, a horizontal portion 430b on an upper surface of the first substrate 420 of the second substrate 430, as shown in FIG. 29, may be provided to have the same height as the upper surface of the first substrate 420.

Specifically, referring to FIG. 29, a trench 42T may be formed in the first substrate 420, and the horizontal portion 430b of the second substrate 430 may be filled in the trench 42T. A depth 42D of the trench 42T may be equal to a thickness of the horizontal portion 430b of the second substrate 430.

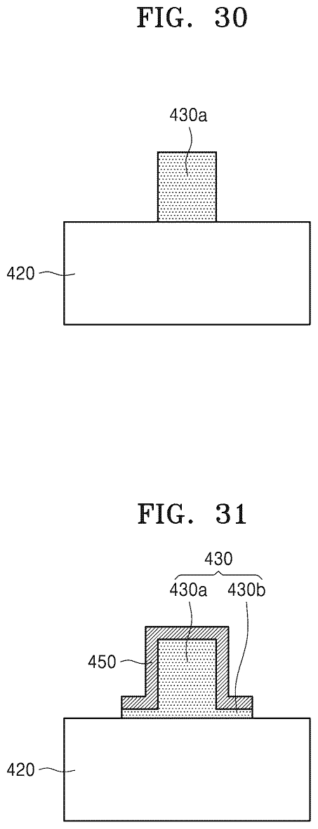

In some examples, the second substrate 430 may have only the vertical portion 430a without the horizontal portion 430b as shown in FIG. 30.

Referring back to FIG. 26, after the precursor layer 440 is formed on the second substrate 430, as described with reference to FIGS. 9A to 10D or FIGS. 16 to 18, the precursor layer 440 is liquefied, and the 2D semiconductor material layer 450 may be selectively formed only on the second substrate 430 (refer to FIG. 31).

In FIG. 31, the second substrate 430 may have the form shown in FIG. 29, and only the vertical portion 430a may exist as shown in FIG. 30.

A planar shape of the 2D semiconductor material layer 450 of FIG. 31 may be the same as that of the 2D semiconductor material layer 350 of FIG. 18. Accordingly, when electrode layers separated from each other are formed on the 2D semiconductor material layer 450 of FIG. 31, the electrode layers may be formed in the same shape as the first and second electrode layers 372 and 374 of FIG. 19.

In FIG. 31, the 2D semiconductor material layer 450 may be formed to have a substantially uniform thickness along the surface of the second substrate 430, and because the vertical portion 430a of the second substrate 430 has a fin shape, an outer shape of the 2D semiconductor material layer 450 may also be a fin shape or a 3D structure having a fin shape. As a result, the channel layer 450 having a 3D structure is formed on the heterogeneous substrates 420+430 having different interface energies.

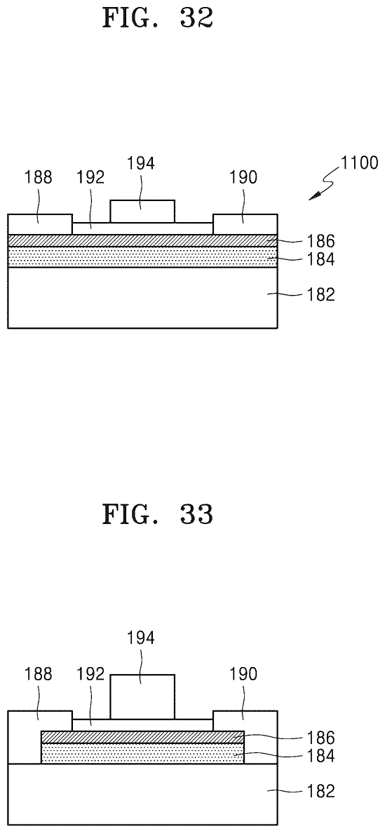

FIG. 32 shows a first electronic device 1100 according to some example embodiments.

Referring to FIG. 32, a first substrate 182 and a second substrate 184 are sequentially stacked. In some examples, the first substrate 182 may be the first substrate 120 described with reference to FIGS. 1 to 11, or may have the characteristics of the first substrate 120. The second substrate 184 may be the second substrate 130 described with reference to FIGS. 1 to 11, or may have the characteristics of the second substrate 130. The first substrate 182 may be expressed as a first material layer, and the second substrate 184 may be expressed as a second material layer.

A 2D channel layer 186 is formed on the second substrate 184. In some examples, the 2D channel layer 186 may be the 2D semiconductor material layer 140 described with reference to FIGS. 1 to 11, or the 2D channel layer formed according to the method of manufacturing the 2D semiconductor material layer 140. First and second electrode layers 188 and 190 are provided on the 2D channel layer 186 to be separated from each other. The first and second electrode layers 188 and 190 may directly contact the 2D channel layer 186. One of the first and second electrode layers 188 and 190 may be a source electrode, and the other may be a drain electrode. A gate insulating layer 192 is disposed on the 2D channel layer 186 between the first and second electrode layers 188 and 190. The gate insulating layer 192 may cover an entire 2D channel layer 186 between the first and second electrode layers 188 and 190. The gate insulating layer 192 may include an insulating oxide film or a nitride film. A third electrode layer 194 is formed on the gate insulating layer 192. The third electrode layer 194 is separated from the first and second electrode layers 188 and 190 and electrically insulated. The third electrode layer 194 may be a control electrode that regulates the flow of carriers (e.g., electrons) flowing through the 2D channel layer 186. In some examples, the third electrode layer 194 may be a gate electrode.

In some examples, the first electronic device 1100 may be a field effect transistor including a 2D channel layer.

FIG. 33 shows a modification of the first electronic device 1100 of FIG. 32.

As depicted in FIG. 33, the second substrate 184 is formed on a partial region of an upper surface of the first substrate 182, the 2D channel layer 186 covers an entire upper surface of the second substrate 184, and the first and second electrode layers 188 and 190 may be formed on an upper portion of the first substrate 182 around the second substrate 184. The first and second electrode layers 188 and 190 may cover a side surface of the second substrate 184 and a side surface of the 2D channel layer 186 and extend onto an upper surface of the 2D channel layer 186.

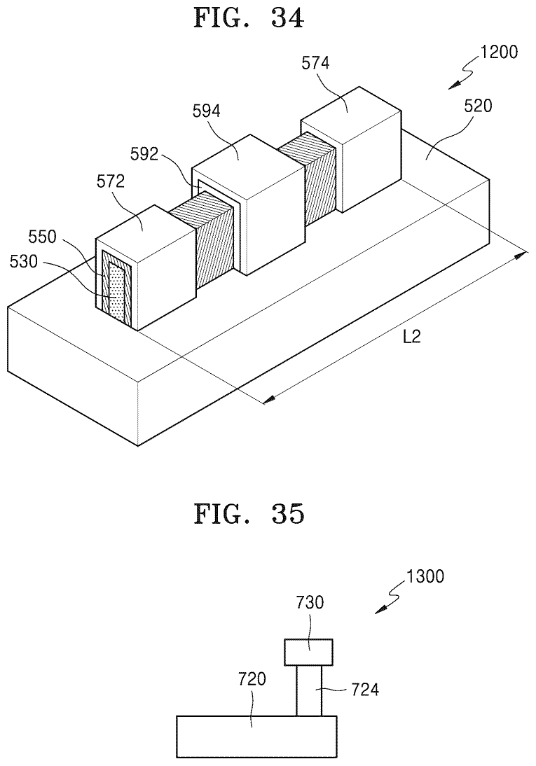

FIG. 34 is a 3D view of a second electronic device 1200 according to some example embodiments, and shows a fin-type transistor in three dimensions.

Referring to FIG. 34, an insulating layer structure 530 in the form of a fin shape and having a second length L2 in a given direction is present on a substrate 520. A material of the substrate 520 may be the same as that of the first substrate 120 described with reference to FIGS. 1 to 11. A material of the insulating layer structure 530 may be the same as that of the second substrate 130 described with reference to FIGS. 1 to 11.

The insulating layer structure 530 has the same shape as that shown in FIG. but may have the shape shown in FIGS. 28 and 29.

Side and upper surfaces of the insulating layer structure 530 are covered with a 2D channel layer 550. A material of the 2D channel layer 550 may be the same as the material of the 2D channel layer 450 described with reference to FIG. 31.

The 2D channel layer 550 may be formed by the method described with reference to FIGS. 26 and 31.

Reference numeral 572 denotes a first electrode layer, and 574 denotes a second electrode layer. One of the first and second electrode layers 572 and 574 may be a source electrode, and the other may be a drain electrode. Reference numeral 594 denotes a gate electrode. A gate insulating layer 592 is present between the gate electrode 594 and the 2D channel layer 550. The 2D channel layer 550 between the first and second electrode layers 572 and 574 and the gate electrode 594 may be covered with a gate insulating layer 592.

FIG. 35 shows a third electronic device 1300 according to some example embodiments. The third electronic device 1300 may be a memory device.

The third electronic device 1300 may include a structure in which a data storage element 730 is connected to a switching device 720 that controls the flow of a current. The switching device 720 and the data storage element 730 may be connected by a conductive layer 724. In some examples, the conductive layer 724 may be a conductive plug that fills a via hole (not shown) between the switching device 720 and the data storage element 730. In some examples, the switching device 720 may include a field effect transistor. In some examples, the switching device 720 may include the first electronic device 1100 shown in FIG. 32. When the switching device 720 includes the first electronic device 1100 of FIG. 32, the conductive layer 724 may be connected to the second electrode layer 190. In some examples, the data storage element 730 may include a volatile storage unit in which data disappears when power is turned off or a non-volatile storage unit in which data is not lost even after power is turned off. In some examples, the data storage element 730 may include a capacitor.

Next, electronic apparatuses according to some example embodiments will be described. The electronic apparatuses according to some example embodiments may include the electronic devices according to the embodiment described above.

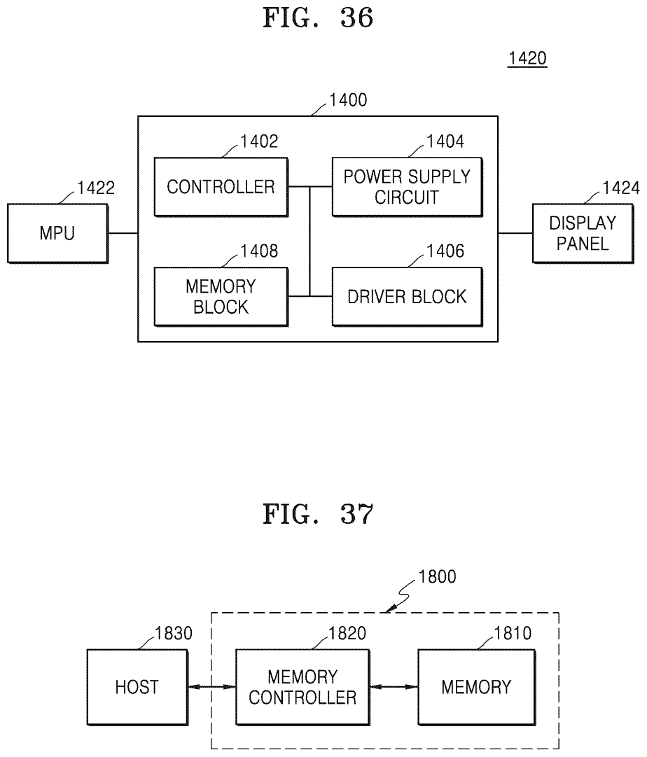

FIG. 36 shows a block diagram of a display driver IC (DDI) 1400 and a display device 1420 including the DDI 1400 as a first electronic apparatus according to some example embodiments.

Referring to FIG. 36, the DDI 1400 may include a controller 1402, a power supply circuit unit 1404, a driver block 1406, and a memory block 1408. The controller 1402 receives and decodes a command applied from a main processing unit (MPU) 1422 and controls each block of the DDI 1400 to implement an operation according to the command. The power supply circuit 1404 generates a driving voltage in response to the control of the controller 1402. The driver block 1406 drives a display panel 1424 using a driving voltage generated by the power supply circuit unit 1404 in response to the control of the controller 1402. The display panel 1424 may be a liquid crystal display panel or a plasma display panel. The memory block 1408 is a block that temporarily stores a command input to the controller 1402 or control signals output from the controller 1402 or stores necessary data, and includes a volatile memory (e.g., RAM) and/or a non-volatile memory. In some examples, the controller 1402 may include the electronic device according to the embodiment described above (e.g., the third electronic device of FIG. 35). In some examples, the units and/or blocks included in the DDI 1400 may include a switching device, and the switching device may include one of the electronic devices shown in FIGS. 32 to 34.

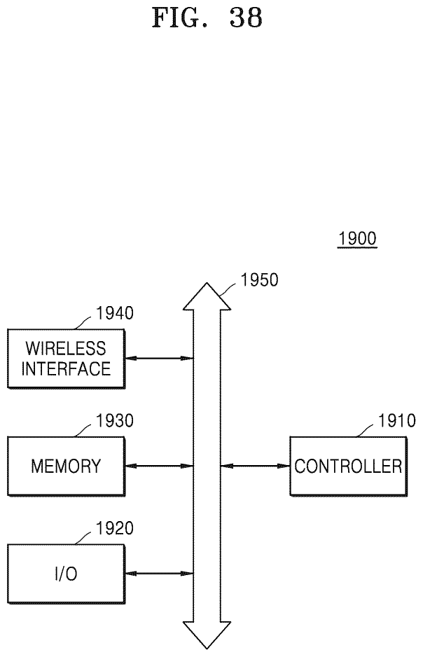

FIG. 37 is a block diagram illustrating an electronic system 1800 as a second electronic apparatus according to some example embodiments.

Referring to FIG. 37, the electronic system 1800 includes a memory 1810 and a memory controller 1820. The memory controller 1820 may control the memory 1810 to read data from and/or write data to the memory 1810 in response to a request from the host 1830.

In some examples, the memory 1810 may include the electronic device according to the embodiment described above (e.g., the third electronic device of FIG. 35). In some examples, the memory 1810 and the memory controller 1820 of the electronic system 1800 may include a switching device, and the switching device may include one of the electronic devices shown in FIGS. 32 to 34.

FIG. 38 is a block diagram of an electronic system 1900 as a third electronic apparatus according to some example embodiments.

Referring to FIG. 38, the electronic system 1900 may configure a wireless communication device or a device capable of transmitting and/or receiving information in a wireless environment. The electronic system 1900 includes a controller 1910, an input/output device 1920, a memory 1930, and a wireless interface 1940, and these components are interconnected to each other through a bus 1950.

The controller 1910 may include at least one of a microprocessor, a digital signal processor, and a processing device similar thereto. The input/output device 1920 may include at least one of a keypad, a keyboard, and a display.

The memory 1930 may be used to store instructions executed by the controller 1910. For example, the memory 1930 may be used to store user data. In some examples, the memory 1930 may include the electronic device according to the embodiment described above (e.g., the third electronic device of FIG. 35).

In some examples, the components, that is, the controller 1910, the input/output device 1920, the memory 1930, and wireless interface 1940, included in the electronic system 1900 may include a switching device, and the switching device may include one of the electronic devices shown in FIGS. 32 to 34.

The electronic system 1900 may use the wireless interface 1940 to transmit/receive data over a wireless communication network. The wireless interface 1940 may include an antenna and/or a wireless transceiver. In some embodiments, the electronic system 1900 may be used in a communication interface protocol of a third-generation communication system, for example, code division multiple access (CDMA), global system for mobile communications (GSM), north American digital cellular (NADC), extended-time division multiple access (E-TDMA), and/or wide band code division multiple access (WCDMA).

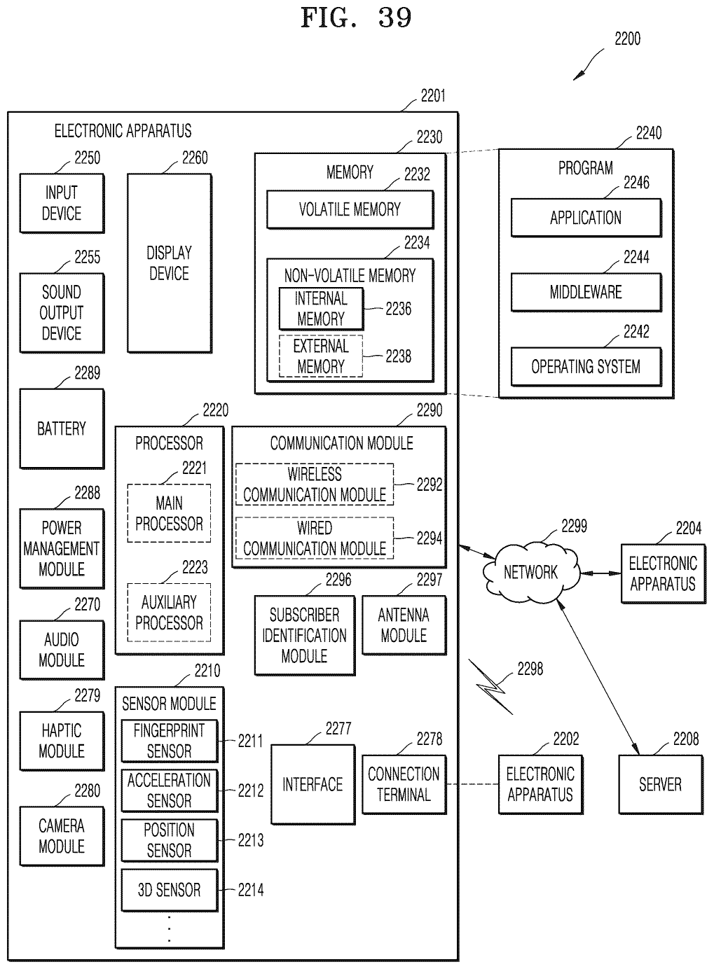

FIG. 39 is a block diagram showing a schematic configuration of a fourth electronic apparatus according to some example embodiments.

Referring to FIG. 39, in a network environment 2200, an electronic apparatus 2201 may communicate with another electronic apparatus 2202 through a first network 2298 (a short-range wireless communication network, etc.) or may communicate with another electronic apparatus 2204 and/or a server 2208 through a second network 2299 (a remote wireless communication network). The electronic apparatus 2201 may communicate with the electronic apparatus 2204 through the server 2208. The electronic apparatus 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. In the electronic apparatus 2201, some of these components (e.g., the display device 2260) may be omitted or other components may be added. Some of these components may be implemented as one integrated circuit. For example, a fingerprint sensor 2211 of the sensor module 2210, an iris sensor, an illuminance sensor, etc. may be implemented in a form embedded in the display device 2260 (a display, etc.).

The processor 2220 may execute software (such as a program 2240) to control one or a plurality of other components (hardware, software components, etc.) of the electronic apparatus 2201 connected to the processor 2220, and may perform various data processing or operations. As part of data processing or operations, the processor 2220 may load commands and/or data received from other components (the sensor module 2210, the communication module 2290, etc.) into a volatile memory 2232, and may process commands and/or data stored in the volatile memory 2232, and store resulting data in a non-volatile memory 2234. The processor 2220 may include a main processor 2221 (a central processing unit, an application processor, etc.) and an auxiliary processor 2223 (a graphics processing unit, an image signal processor, a sensor hub processor, a communication processor, etc.) that may be operated independently or together with the main processor 2221. The auxiliary processor 2223 may use less power than the main processor 2221 and may perform a specialized function.

The auxiliary processor 2223 may control functions and/or states related to some of the components (e.g., the display device 2260, the sensor module 2210, the communication module 2290) of the electronic apparatus 2201 instead of the main processor 2221 while the main processor 2221 is in an inactive state (sleep state), or together with the main processor 2221 while the main processor 2221 is in an active state (application execution state). The auxiliary processor 2223 (an image signal processor, a communication processor, etc.) may be implemented as a part of other functionally related components (the camera module 2280, the communication module 2290, etc.).

The memory 2230 may store various data required by components of the electronic apparatus 2201 (the processor 2220, the sensor module 2276, etc.). The data may include, for example, input data and/or output data for software (such as the program 2240) and instructions related to the command. The memory 2230 may include a volatile memory 2232 and/or a non-volatile memory 2234. The non-volatile memory 2234 may include an internal memory 2236 and an external memory 2238. In some examples, the memory 2230 may include any one of the electronic devices according to the embodiments described above (e.g., the third electronic device of FIG. 35).

The program 2240 may be stored as software in the memory 2230, and may include an operating system 2242, middleware 2244, and/or an application 2246.

The input device 2250 may receive commands and/or data to be used in a component (e.g., the processor 2220) of the electronic apparatus 2201 from the outside of the electronic apparatus 2201 (e.g., a user). The input device 2250 may include a microphone, a mouse, a keyboard, and/or a digital pen (such as a stylus pen).

The sound output device 2255 may output a sound signal to the outside of the electronic device 2201. The sound output device 2255 may include a speaker and/or a receiver. The speaker may be used for general purposes, such as multimedia playback or recording playback, and the receiver may be used to receive incoming calls. The receiver may be integrated as a part of the speaker or may be implemented as an independent separate device.

The display device 2260 may visually provide information to the outside of the electronic device 2201. The display device 2260 may include a control circuit for controlling a display, a hologram device, or a projector and a corresponding device. The display device 2260 may include a touch circuitry configured to sense a touch, and/or a sensor circuitry configured to measure the intensity of force generated by the touch (e.g., a pressure sensor, etc.).

The audio module 2270 may convert a sound into an electric signal or, conversely, convert an electric signal into a sound. The audio module 2270 may obtain a sound through the input device 2250 or may output a sound through a speaker and/or headphone of the sound output device 2255 and/or another electronic apparatus (e.g., the electronic apparatus 2202) directly or wirelessly connected to electronic apparatus 2201.

The sensor module 2210 may detect an operating state (power, temperature, etc.) of the electronic apparatus 2201 or an external environmental state (user state, etc.), and may generate an electrical signal and/or data value corresponding to the sensed state. The sensor module 2210 may include a fingerprint sensor 2211, an acceleration sensor 2212, a position sensor 2213, a 3D sensor 2214, and the like, and in addition to the above sensors, may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The 3D sensor 2214 may sense a shape and movement of an object by irradiating a desired and/or alternatively predetermined light to the object and analyzing light reflected from the object, and may include a meta-optical device.

The interface 2277 may support one or more designated protocols that may be used by the electronic apparatus 2201 to connect directly or wirelessly with another electronic apparatus (e.g., the electronic device 2102). The interface 2277 may include a High Definition Multimedia Interface (HDMI), a Universal Serial Bus (USB) interface, an SD card interface, and/or an audio interface.

The connection terminal 2278 may include a connector through which the electronic apparatus 2201 may be physically connected to another electronic apparatus (e.g., the electronic apparatus 2202). The connection terminal 2278 may include an HDMI connector, a USB connector, an SD card connector, and/or an audio connector (e.g., a headphone connector).

The haptic module 2279 may convert an electrical signal into a mechanical stimulus (vibration, movement, etc.) or an electrical stimulus that the user may perceive through tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly included in the camera module 2280 may collect light emitted from an object, which is an imaging target.

The power management module 2288 may manage power supplied to the electronic apparatus 2201. The power management module 388 may be implemented as part of a Power Management Integrated Circuit (PMIC).

The battery 2289 may supply power to components of the electronic apparatus 2201. The battery 2289 may include a non-rechargeable primary cell, a rechargeable secondary cell, and/or a fuel cell.

The communication module 2290 establishes a direct (wired) communication channel and/or wireless communication channel between the electronic apparatus 2201 and other electronic apparatuses (the electronic apparatus 2202, an electronic apparatus 2204, server 2108, etc.) and performing communication through an established communication channel. The communication module 2290 may include one or more communication processors that operate independently of the processor 2220 (e.g., an application processor) and support direct communication and/or wireless communication. The communication module 2290 may include a wireless communication module 2292 (a cellular communication module, a short-range wireless communication module, a Global Navigation Satellite System (GNSS, etc.) communication module) and/or a wired communication module 2294 (a Local Area Network (LAN) communication module, or a power line communication module, etc.). Among these communication modules, a corresponding communication module may communicate with other electronic apparatuses through the first network 2298 (a short-range communication network, such as Bluetooth, WiFi Direct, or Infrared Data Association (IrDA)) or the second network 2299 (a telecommunication network, such as a cellular network, the Internet, or a computer network (LAN) and WAN, etc.). The various types of communication modules may be integrated into one component (a single chip, etc.) or implemented as a plurality of components (plural chips) separate from each other. The wireless communication module 2292 may identify and authenticate the electronic apparatus 2201 within a communication network, such as the first network 2298 and/or the second network 2299 by using subscriber information (such as, International Mobile Subscriber Identifier (IMSI)) stored in a subscriber identification module 2296.

The antenna module 2297 may transmit or receive signals and/or power to and from the outside (other electronic apparatuses, etc.). The antenna may include a radiator having a conductive pattern formed on a substrate (PCB, etc.). The antenna module 2297 may include one or a plurality of antennas. When a plurality of antennas is included in the antenna module 2297, an antenna suitable for a communication method used in a communication network, such as the first network 2298 and/or the second network 2299 from among the plurality of antennas may be selected by the communication module 2290. Signals and/or power may be transmitted or received between the communication module 2290 and another electronic apparatus through the selected antenna. In addition to the antenna, other components (an RFIC, etc.) may be included as a part of the antenna module 2297.

Some of the components are connected to each other through a communication method between peripheral devices (a bus, a General Purpose Input and Output (GPIO), a Serial Peripheral Interface (SPI), a Mobile Industry Processor Interface (MIPI), etc.), and may interchange signals (commands, data, etc.).

The command or data may be transmitted or received between the electronic apparatus 2201 and the external electronic apparatus 2204 through the server 2208 connected to the second network 2299. The other electronic apparatuses 2202 and 2204 may be the same or different types of electronic apparatus 2201. All or some of operations performed in the electronic apparatus 2201 may be performed in one or more of the other electronic apparatuses 2202, 2204, and 2208. For example, when the electronic apparatus 2201 needs to perform a function or service, the electronic apparatus 2201 may request one or more other electronic apparatuses to perform part or all function or service instead of executing the function or service itself. One or more other electronic apparatuses receiving the request may execute an additional function or service related to the request, and transmit a result of the execution to the electronic apparatus 2201. For this purpose, cloud computing, distributed computing, and/or client-server computing technologies may be used.

In the network environment 2200, at least the electronic apparatus 2201 may include a switching device (e.g., a transistor), and the switching device may include one of the electronic devices shown in FIGS. 32 to 34.

The method of manufacturing 2D channel layer uses a principle in which a liquid precursor is selectively transferred onto a substrate having a relatively low interfacial energy. Different types of substrates having different interfacial energies are used, and a substrate having a relatively low interfacial energy is pre-patterned in the form of a desired 2D channel layer. The substrate with low interfacial energy may be patterned in various shapes, such as circles or polygons according to the desired shape of the 2D channel layer.

Because the liquid precursor is selectively moved onto a substrate having a relatively low interfacial energy, the 2D channel layer may be formed only on the substrate patterned to match the shape of the 2D channel layer.

Therefore, when the method of manufacturing a 2D channel layer according to some example embodiments, a patterning process for the 2D channel layer is not required, and thus, side effects (e.g., channel damage, change in physical properties of a channel material, etc.) due to patterning of the 2D channel layer in a method of manufacturing a 2D channel layer of the related art may be prevented.

In addition, in the method of manufacturing a 2D channel layer according to some example embodiments, the 2D channel layer is selectively formed on a substrate having a relatively low interfacial energy, and thus, it is possible to prevent the 2D channel layer from growing in a random direction. In addition, the substrate on which the 2D channel layer is formed to a form of a desired 2D channel layer before the 2D channel layer is formed, and the shape of the 2D channel layer may be precisely limited while forming the 2D channel layer in various forms. Accordingly, in the case of a device (e.g., a field effect transistor) to which the method of manufacturing a 2D channel layer according to some example embodiments is applied, a problem caused by a characteristic deviation between devices may be solved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU) , an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A layer structure comprising:
a first substrate;
a second substrate surrounded by the first substrate; and
a two-dimensional (2D) channel layer on the second substrate, wherein
an interfacial energy of the second substrate is less than an interfacial energy of the first substrate.

2. The layer structure of claim 1, wherein
the first substrate includes a trench, and
the second substrate is in the trench.

3. The layer structure of claim 2, wherein
the second substrate is along a surface of the trench, and
the 2D channel layer is along a surface of the second substrate.

4. The layer structure of claim 3, wherein the 2D channel layer fills the trench in the first substrate.

5. The layer structure of claim 2, wherein the second substrate completely fills the trench.

6. The layer structure of claim 2, wherein
the second substrate completely fills the trench, and
an upper surface of the second substrate higher than an upper surface of the first substrate.

7. The layer structure of claim 2, wherein
the trench is a step-type trench including portions having different widths, and
the first substrate and the second substrate have a same height.

8. The layer structure of claim 1, wherein the first substrate and the second substrate have a same height.

9. The layer structure of claim 1, wherein the second substrate has a fin shape and protrudes in a direction perpendicular to a surface of the first substrate.

10. The layer structure of claim 1, wherein the 2D channel layer includes a 2D semiconductor material layer.

11. An electronic device comprising:
the layer structure of claim 1; and
a plurality of electrode layers on the layer structure, wherein
the first substrate is a substrate,
the two-dimensional (2D) channel layer on the second substrate is on the substrate;
the plurality of electrode layers include a first electrode layer and a second electrode layer separated from each other on the 2D channel layer; and
the plurality of electrode layers further include a third electrode layer on the 2D channel layer between the first electrode layer and the second electrode layer, and
the third electrode layer is spaced part from the 2D channel layer.

12. An electronic apparatus comprising the electronic device of claim 11.

13. A memory device comprising:
a switching device; and
a data storage element connected to the switching device,
wherein the switching device comprises the layer structure of claim 1.

14. An electronic apparatus comprising the memory device of claim 13.

15. A method of manufacturing a two-dimensional (2D) channel layer, the method comprising:
forming a first substrate;
forming a second substrate surrounded by the first substrate;
forming a precursor layer on one of the first substrate and the second substrate, the precursor layer for forming a 2D channel; and
transforming the precursor layer into a liquid precursor layer,
wherein an interfacial energy of the second substrate is less than an interfacial energy of the first substrate.

16. The method of claim 15, wherein the forming the second substrate surrounded by the first substrate comprises:
forming a trench in the first substrate; and
forming the second substrate in the trench.

17. The method of claim 15, wherein the second substrate is formed to have a fin shape in a direction perpendicular to the first substrate.

18. The method of claim 15, further comprising:
the second substrate comprises a main substrate and an auxiliary substrate,
the auxiliary substrate is connected to the main substrate,
an area of the auxiliary substrate is smaller than an area of the main substrate,
the auxiliary substrate includes a first portion and a second portion,
the first portion of the auxiliary substrate has a constant width,
the second portion of the auxiliary substrate is between the main substrate and the first portion of the auxiliary substrate,
a portion of the second portion of the auxiliary substrate is directly connected to the main substrate,
a width of the portion of the second portion of the auxiliary substrate is narrower than a width of the first portion of the auxiliary substrate,
the forming the precursor layer forms the precursor layer on the auxiliary substrate.

19. The method of claim 15, wherein the forming the precursor layer comprises one of:
forming the precursor layer on a partial region of the second substrate;
forming the precursor layer on a region including a boundary between the first substrate and the second substrate and a portion of the first substrate and the second substrate, the portion of the first substrate and the second substrate being on both sides of the boundary; and
forming the precursor layer on a partial region of the first substrate in contact with the boundary.

20. The method of claim 15, wherein the second substrate is formed in a same shape as a planar shape of a 2D channel layer to be formed.
